(19) United States
(12) Patent Application Publication
(10) Pub. No.: US 2007/0017804 A1
(43) Pub. Date: Jan. 25, 2007

(54) Device for improving plasma activity PVD-reactors

(75) Inventors: Toril Myrtveit, Kungsangen (SE); Markus Rodmar, Vallentuna (SE); Torbjorn Selinder, Stockholm (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB

(21) Appl. No.: 11/490,502

(22) Filed: Jul. 21, 2006

(30) Foreign Application Priority Data
Jul. 22, 2005 (SE) 0501717-3

(51) Int. Cl. C23C 14/00

(52) U.S. Cl. 204/298.16

(57) ABSTRACT

The present invention relates to a device for improving plasma activity in a magnetron sputtering reactor containing substrates to be coated where a primary plasma is created by a DC or AC voltage applied between the substrates and an additional electrode. Increased plasma activity is obtained by thermionic emission of electrons from a hot filament heated by either DC or AC current or combinations thereof. The device is particularly useful for increasing the adhesion of layers deposited by magnetron sputtering on cutting tool inserts made of cemented carbide, high speed steels, cermets, ceramics or cubic boron nitride.

### BACKGROUND OF THE INVENTION

The present invention relates to a device for achieving an enhanced plasma activity in PVD reactors. Due to the increased plasma density the invention enables operation of sputter etching at much lower pressure than otherwise possible in a magnetron sputtering PVD coating chamber. Thus, gas phase scattering is avoided and problems with redeposition and contamination of sputter cleaned surfaces of 3-D objects are eliminated. The invention allows for sputter etching substrates in a magnetron sputtering system at bias values suitable to avoid impact damage.

Modern high productivity chip forming machining of metals requires reliable tool inserts with high wear resistance, good toughness properties and excellent resistance to plastic deformation.

This has so far been achieved by employing cemented carbide inserts coated with wear resistant layers like TiN, TiₓAl_{y}N, CrₓAl_{y}N and Al₂O₃. Such layers have been commercially available for many years. Several hard layers in a multilayer structure generally build up a coating. The sequence and the thickness of the individual layers are carefully chosen to suit different cutting application areas and work-piece materials.

The coatings are most frequently deposited by Chemical Vapor Deposition (CVD), Moderate Temperature CVD (MTCVD) or Physical Vapor Deposition (PVD) techniques.

CVD layers are generally deposited at a temperature between 900 and 1000° C. and MTCVD at 700-800° C. using acetonitrile, CH₃CN, as a reactant. The advantages of CVD are good adhesion, relatively thick layers can be grown and the possibility to deposit insulating layers like Al₂O₃.

PVD refers to a number of methods in which a metal vapor is provided in a suitable atmosphere to form the desired compound to be deposited by thermal evaporation, sputtering, ion plating, arc evaporation etc. at a temperature of from about 100 to about 700° C. With PVD, many more materials can be deposited than in CVD, and the layers have compressive stress as opposed to tensile stress in CVD-layers. The low deposition temperature on the other hand causes problems with the adhesion of the layers. For that reason, coating of substrates with PVD-technology usually involves several cleaning steps.

The substrates are generally pre-treated before entering the PVD reactor using, e.g., blasting, wet etching and/or cleaning in solvents. Immediately preceding deposition, an in vacuo sputter-etching step is most often included to further clean the substrates from moisture, native oxides and other impurities not removed during the pretreatment step. The etching step is generally performed by providing a plasma at a pressure in the range of from about 0.2 to about 1.0 Pa in the reactor. By applying a negative bias to the substrates, ions from this plasma bombard the substrates and thus clean the surfaces thereof. The bias should be high enough to sputter etch the substrates, but not high enough to damage the surface. Typical bias values are approximately −200 V, whereas values below about −500 V start to cause radiation damage by ion impact. The plasma is commonly generated by an electrical discharge in a rare gas atmosphere, e.g., Ar, inside the PVD reactor. A low plasma activity in this step may lead to incomplete etching, anisotropic etching and/or redeposition of sputtered material. More redeposition entails the higher the Ar pressure during etching. This is due to the fact that as the mean free path of gas molecules shrinks the probability of gas phase scattering increases and hence a cloud of etched material is likely to redeposit and contaminate the surface all over again. Redeposition and anisotropic etching is especially a concern when working with three-dimensional structures where parts thereof will be ‘shadowed’ from the plasma; that is, surfaces that do not have the main plasma in direct line-of-sight.

Sputter-etching can be achieved in a number of different ways. One possibility is to ignite plasma in an Ar atmosphere using a hot W filament, as disclosed in GB-A-2049560, herein incorporated by reference. Other, more chemically reactive gases, e.g., H₂ and fluorocarbons, can also be present to enhance the process. The thermionic filament should be protected from the plasma as it will otherwise also be etched. This is achieved by placing the filament in a separate filament chamber. The electrons must in this case be accelerated out of this chamber by an anode situated in the opposite part of the etching chamber. The electrons that traverse the chamber ionize the Ar gas which plasma is homogeneously distributed and may be used to sputter etch the substrates. The electron channel throughout the height of the chamber must be diverged radially using large magnetic coils located on the top and the bottom of the reactor. The technology is quite complicated and demands a high degree of control in order to distribute the plasma evenly over the substrates. One advantage of the above method is that the etching may be conduced at low pressures, approximately 0.2 Pa, which reduces redeposition problems.

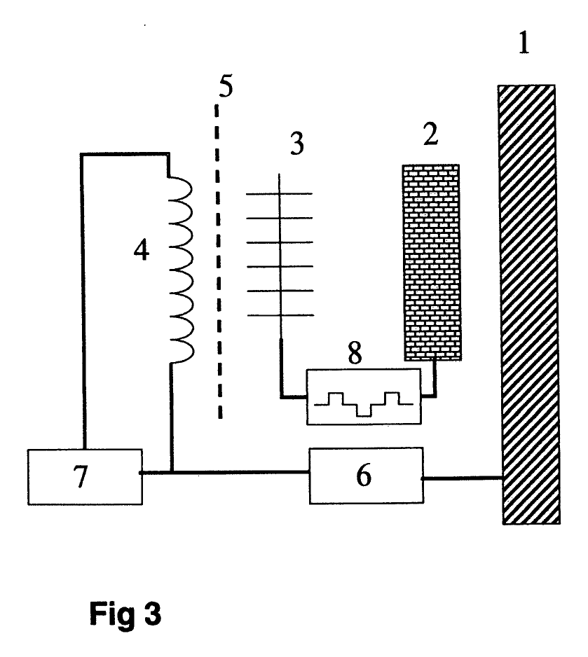

An elegant alternative way of creating homogenous sputter-etching plasma without rigorous controls is to apply an alternating voltage between substrates and a counter electrode, as disclosed in WO 97/22988. The counter electrode can be a magnetron source used also in the deposition process, which follows the etching process. The electrical connections are schematically shown in FIG. 3 together with the present invention. The prior art consists of the circuit made by the substrates (3), the power supply (8), and the magnetron source (2). This method works fairly well at pressures above 0.8 Pa, but unfortunately at this high pressure redeposition of etched material is often seen on truly 3-dimensional substrates. The high pressure needed for operation, generating the etching plasma is due to the low degree of ionization seen in magnetron sputtering technology. In addition, valuable sputter material is unfortunately used for sputter cleaning.

In U.S. Pat. No. 5,294,322 it is taught how an arc discharge covered by a shutter may be used as a low voltage electron source. Again the electrons are collected at an anode. As the electrons traverse the coating chamber ions of a rare gas are generated by electron-atom impact and a separate power supply is used to accelerate these ions towards the substrates. The drawback is that either a separate dedicated arc source must be used for the electron generation, which steals valuable chamber wall space, or a shuttered deposition source may be used in which case valuable coating material is lost in the sputter etch cleaning step.

### OBJECTS AND SUMMARY OF THE INVENTION

It is thus an object of the present invention to provide a device and a method for increasing the plasma intensity during sputter-etching of substrates while keeping the technology simple.

In one aspect of the invention there is provided a device for improving plasma activity in a coating reactor containing substrates to be coated, where a primary plasma is created by a DC or AC voltage applied between the substrates and at least one additional electrode, said device comprising a thermionic emitter, heated by either DC or AC current or combinations thereof.

In another aspect of the invention there is provide the use of that device in a PVD reactor to achieve enhanced sputter etching prior to the deposition of layers on cutting tool inserts made of cemented carbide, high speed steels, cermets, ceramics, cubic boron nitride or metals steel, as well as coating of metal wires, rods and bands, preferably cutting tool inserts made of cemented carbide, high speed steels, cermets, ceramics or cubic boron nitride.

### BRIEF DESCRIPTION OF THE DRAWINGS

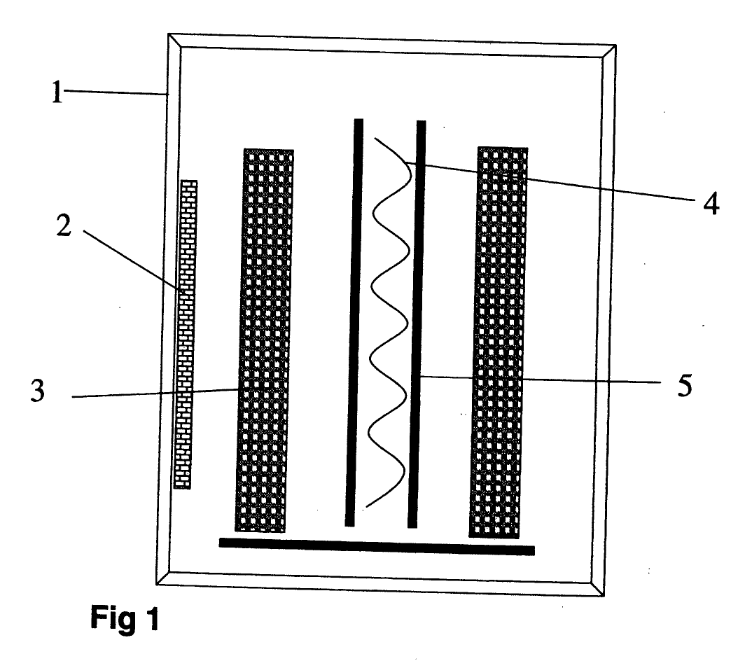

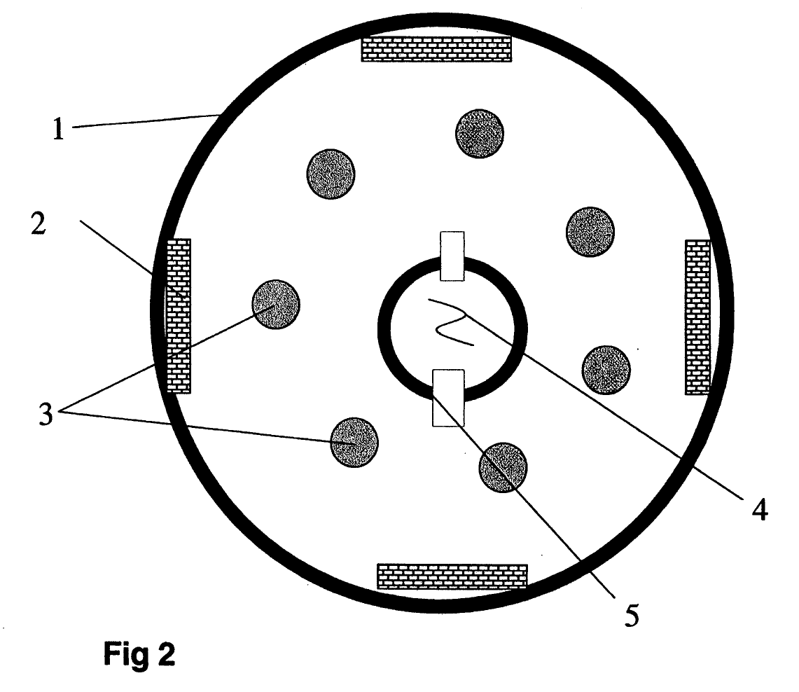

The Figures are schematic representations of the magnetron deposition system according to the invention in side view (FIG. 1), top view (FIG. 2), and the electrical connections according to one representation of the invention (FIG. 3) in which

1—Reactor wall

2—Magnetron

3—Substrates to be coated

4—Filament

5—Cage

6—Power supply to accelerate electrons out from the hot filament

7—Power supply connected to the hot filament

8—Power supply to create the primary plasma.

### DETAILED DESCRIPTION OF THE PREFERRED EMBODIMENTS

The present invention thus relates to a device for improving plasma activity in a PVD reactor containing substrates to be coated. According to the present invention a primary plasma is ignited by applying an alternating or direct voltage between the substrates and an additional electrode. This electrode can be at least one separate dedicated electrode, the reactor wall, at least one PVD-deposition source, magnetron and/or arc source, as described in WO 97/22988, herein incorporated by reference, or preferably at least one magnetron pair or a dual magnetron sputtering (DMS) pair. The DMS technology consists of two magnetron sputtering sources connected to a bipolar pulsed power supply. To increase the plasma activity by thermionic emission of electrons, a hot filament is installed in the reactor, preferably centrally along the symmetry-axis and preferably extending from top to bottom of the reactor. With filament is meant any adequate design such as thread, mesh, band or similar. The filament is preferably helix-wound or otherwise constructed to allow for thermal expansion/shrinkage. The filament is preferably made from efficient electron-emitting material such as W, thoriated W or a coated filament, where the coating is an efficient electron emitter such as rare earth oxides, carbon nanotubes, barium oxides etc. The filament can be in the form of one long filament or as several shorter filaments connected either in series or in parallel or combinations thereof. Either DC or AC current or combinations thereof can be used for heating the filament. The filament preferably is situated in the center of the reactor and the electrons are evenly distributed in the z-direction (height-axis) of the reactor. To ensure effective emission of electrons from the filament as well as a good radial distribution, a DC or bipolar voltage can be applied between the filament as a cathode and a corresponding anode. This anode can be the reactor wall, one or more separate electrodes, or one or more of the electrodes used for creating the primary plasma. The electrons generate plasma as they traverse the separating space between the cathode filament and the anode, giving rise to Ar ionization in the process. This enhanced plasma density enables sputter etching at much lower pressure in the range of from about 0.1 to about 0.2 Pa than otherwise possible in a magnetron deposition system. The increased ionization enables operation of sputter etching at substrate bias values around −200 V, giving less ion impact damage than by prior art technology for magnetron sputtering systems.

The filament is exposed to the plasma and thus erodes with time. Due to this, the filament must either be replaced on a routine basis, or protected by a cage comprising of, e.g., a metal cylinder, a mesh, or metal rods surrounding the filaments but with small slits from which the emitted electrons can be accelerated out into the plasma. The potential of the cage is in the range from the potential of the hot filament to the potential of the suitable anode.

The device according the invention is particularly useful in a magnetron sputtering system.

The invention also relates to the use of the device to enhance the plasma activity when utilized for sputter etching prior to the deposition of layers on cutting tool inserts made of cemented carbide, high speed steels, cermets, ceramics, cubic boron nitride or metals like steel, as well as coating of metal wires, rods and bands particularly cutting tool inserts made of cemented carbide, high speed steels, cermets, ceramics or cubic boron nitride.

The invention is additionally illustrated in connection with the following examples, which are to be considered as illustrative of the present invention. It should be understood, however, that the invention is not limited to the specific details of the examples.

### EXAMPLE 1

### Prior Art

Sputter etching of cemented carbide cutting inserts was performed according to the system described in WO 97/22988. A plasma was ignited at a moderate pressure of 0.8 Pa and a substrate-target voltage of 800 V, which was the minimum voltage to operate the etching. A current flowing through the substrates of 2 A was achieved. This substrate current was limited by the ion density resulting from using a magnetron as counter electrode. The current was, furthermore, related to the impact by charged ions and was thus a measure of the etch. The substrates showed after this sputter-etching procedure signs of redeposition on shadowed surfaces. The voltage necessary to operate the discharge was high enough to risk impact damage to the substrates.

### EXAMPLE 2

### Invention

Example 1 was repeated utilizing the system as described above but with the addition of a centrally situated hot W-filament, as indicated in FIG. 2. By heating the filament with 11 A and applying a voltage of 360 V between the filament (cathode) and the reactor wall (anode), etching was achieved at 0.2 Pa. With a substrate—Ti-counter electrodes (magnetron sources) voltage of 200 V, a substrate current of 7 A was measured. This voltage was not the minimum etching voltage necessary but selected as appropriate. The substrates were clearly more and deeper etched and showed no signs of redeposition, not even on highly shadowed areas.

Thus, when etching according to the present invention a more efficient etch was obtained, at a lower substrate voltage which implies less impact damage and at a lower pressure thus eliminating redeposition.

### EXAMPLE 3

The inserts from Examples 1 and 2 were, immediately following the etch, coated with a 1.6 μm thick layer of Al₂O₃ using a standard deposition process: DMS using two pairs of magnetrons equipped with Al targets. A background pressure of 0.23 Pa Ar was maintained for the sputtering gas discharges which were run at 40 kW each. Oxygen reactive gas was fed at 2×30 sccm and controlled by an optical emission feedback circuit. This resulted in crystalline alumina layers. The two sets of inserts were evaluated in a turning test in stainless steel, with the object to determine the adhesion of the coatings. The results indicated that the inserts etched according to prior art technology exhibited extensive flaking while the inserts etched according to the invention showed less flaking and less indications of wear.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. Device for improving plasma activity in a coating reactor containing substrates to be coated, where a primary plasma is created by a DC or AC voltage applied between the substrates and at least one additional electrode, said device comprising a thermionic emitter, heated by either DC or AC current or combinations thereof.

2. A device of claim 1 wherein the hot filament is the cathode of a system and the corresponding anode is one or more separate dedicated electrodes.

3. A device of claim 1 wherein the hot filament is the cathode of a system and the corresponding anode is the reactor wall.

4. A device of claim 2 or 3 wherein the corresponding anode is the at least one additional electrode used to create the primary plasma.

5. A device of claim 1 wherein the hot filament extends from top to bottom in the reactor.

6. A device of claim 5 wherein the filament is either W, thoriated W or any coated filament and the coating is an efficient electron emitter.

7. A device of claim 5 wherein the hot filament is protected by a chamber or a cage with small apertures from which the emitted electrons can escape with a potential in the range from the potential of the hot filament to the potential of the corresponding anode.

8. A device of claim 1 wherein the coating reactor is a PVD reactor.

9. A device of claim 1 wherein the thermionic emitter comprises at least one filament.

10. A device of claim 9 wherein the thermionic emitter comprises more than one filament.

11. A device of claim 10 wherein the filaments are connected in series.

12. A device of claim 10 wherein the filaments are connected in parallel.

13. A device of claim 8 wherein the PVD coating system is a magnetron sputtering system.

14. Use of the device of claim 1 in a PVD reactor to achieve enhanced sputter etching prior to the deposition of layers on cutting tool inserts made of cemented carbide, high speed steels, cermets, ceramics, cubic boron nitride or metals steel, as well as coating of metal wires, rods and bands.

15. The use of the device of claim 14 to achieve enhanced sputter etching prior to the deposition of layers on cutting tool inserts made of cemented carbide, high speed steels, cermets, ceramics or cubic boron nitride.
